(19) United States
(12) Patent Application Publication
(10) Pub. No.: US 2011/0310680 A1
(43) Pub. Date: Dec. 22, 2011

(54) Interleave Memory Array Arrangement

(75) Inventors: Yuen H. Chan, Poughkeepsie, NY (US); Michael Kugel, Boeblingen (DE); Raphael Polig, Boeblingen (DE); Tobias Werner, Boeblingen (DE)

(73) Assignee: INTERNATIONAL BUSINESS MACHINES CORPORATION, Armonk, NY (US)

(21) Appl. No.: 12/821,064

(22) Filed: Jun. 22, 2010

(51) Int. Cl. G11C 7/00; G11C 8/00

(52) U.S. Cl. 365/189.011; 365/230.06

(57) ABSTRACT

A memory array includes a plurality of memory cells, wherein each cell of the plurality of memory cells is defined by a row and a column, wherein each row includes a unique identifying address, and wherein each column is associated with one of two sets, the columns arranged such that a column associated with a first set is adjacent to a column of a second set.

### BACKGROUND

The present invention relates to memory arrays, and more specifically, to Static Random Access Memory (SRAM) arrays.

Memory arrays may be arranged in two dimensional sub-arrays. The two dimensional sub-arrays are arranged in word line rows and bit line columns. The word lines are decoded by the word address whereas the bit lines are decoded by the bit address. Data is read and written on the array using an address that identifies a word line and identifies one or more bit lines. The sub-arrays may include one, two, or more sets that share common word line and bit address. Thus, a read or write cycle for an address of a particular word line activates a word line in each set of the sub-array. Activating the word line in each of the sets undesirably consumes power.

### BRIEF SUMMARY

According to one embodiment of the present invention, a memory array includes a plurality of memory cells, wherein each cell of the plurality of memory cells is defined by a row and a column, wherein each row includes a unique identifying address, and wherein each column is associated with one of two sets, the columns arranged such that a column associated with a first set is adjacent to a column of a second set.

According to another embodiment of the present invention, a memory array system includes a read/write controller operative to receive data, a memory array including a plurality of memory cells, wherein each cell of the plurality of memory cells is defined by a row and a column, wherein each row includes a unique identifying address, and wherein each column is associated with one of two sets, the columns arranged such that a column associated with a first set is adjacent to a column of a second set, the memory array operative to store the data in the plurality of memory cells, and an output driver operative to receive and output the data.

According to yet another embodiment of the present invention, a method for accessing a memory array, the method includes receiving an address, decoding the address to determine a word line address uniquely identifying a row in the memory array, and activating memory cells associated with the identified row, wherein the memory cells associated with the identified row are each associated with one of two sets and arranged such that a memory cell associated with a first set is adjacent to a memory cell associated with a second set.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 illustrates a prior art example of a block diagram of a memory array system with two dimensional address decode.

FIG. 2 illustrates a prior art example of a physical sub-array arrangement of the memory array of FIG. 1.

FIG. 3 illustrates a block diagram of an exemplary embodiment of a memory system

FIG. 4 illustrates an exemplary embodiment of the memory array of FIG. 3.

### DETAILED DESCRIPTION

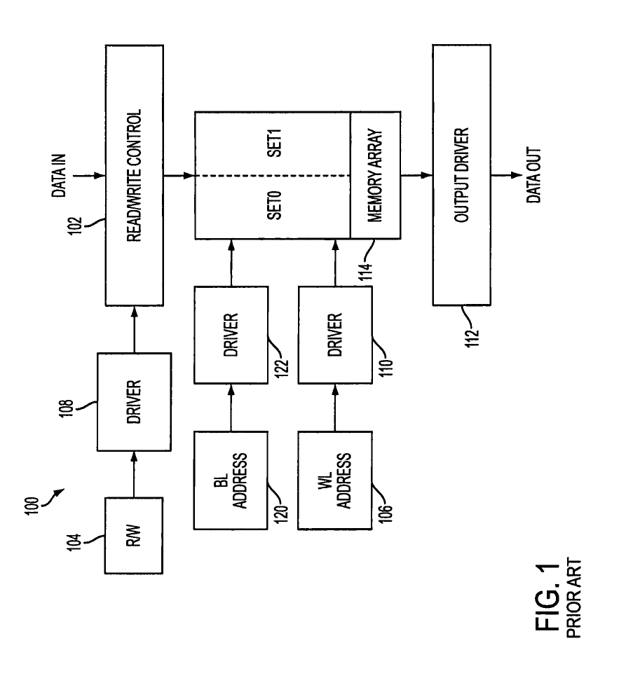

FIG. 1 illustrates the block diagram of a prior art example of a memory array system 100 having a two dimensional address decode. The memory system 100 includes a memory array 114 that receives data from a read/write controller 102 (processor) that receives read/write instructions 104 via a driver 108 (processor). A word line address 106 is sent to the memory array 114 via a driver 110, and a bit line address 120 is sent to the memory array 114 via a driver 122. An output driver 112 receives data from the memory array 114 and outputs the data. The memory array 114 logically consists of two sets (set0 and set1), each set with 256 entries by 56 data bits (not shown). The two sets are accessed concurrently using the same address input. Eight address bits are used to decode 1-out-of-256 logical entries. The eight bit address is further divided into word line decode (7 bits) and bit line or column decode (1 bit) to physically access the memory array.

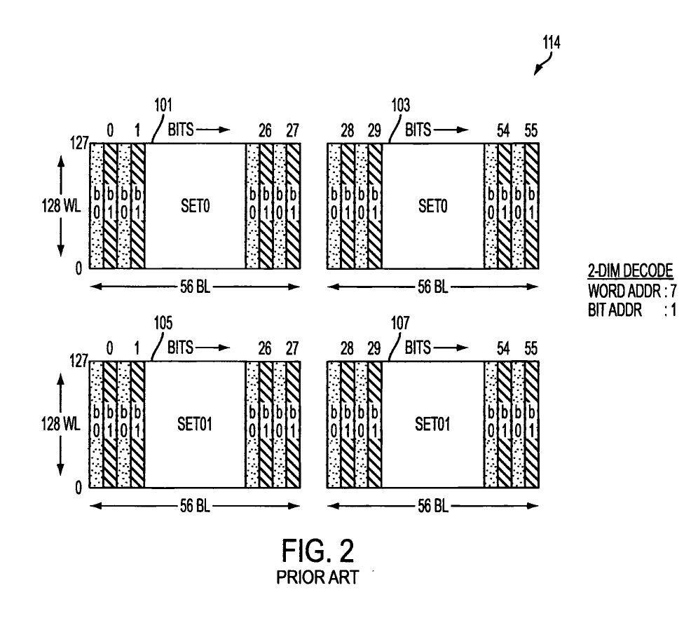

FIG. 2 further illustrates a prior art example of the memory array 114 (of FIG. 1). The memory array 114 includes two sets (set0 and set1) that include four sub-arrays 101, 103, 105, and 107 where set0 includes the sub-arrays 101 and 103 and set1 includes the sub-arrays 105 and 107. Each of the sets includes 128 word line (WL) rows and 112 bit line (BL) columns, where each sub-array includes 56 bit lines. The bit lines are arranged with alternating addresses (b0 and b1). The word lines are spanned across (i.e., shared between) the left and right sub-arrays. In the array 100 an eight bit address may be used that includes seven bits identifying an address of the 128 word lines and a single bit to identify a one of the bit addresses (b0 or b1). In operation a decoded eight bit address will include a seven bit word line address and a one bit, bit address. Since the sets share word line addresses, the decoded seven bit word line address will activate a word line in each of the sets that has the shared word line address and the bit lines (b0 or b1) identified in the bit address. One drawback to the arrangement of the memory array 100 is that additional power is consumed when activating a word line in each set (i.e., two physical word lines are activated, one word line in sub-arrays 101-103, and another word line in sub-arrays 105/107). Since only half of the bit lines (either b0 or b1) along an activated word line are used for reading or writing, the other half are not performing an active function, and therefore wasting power.

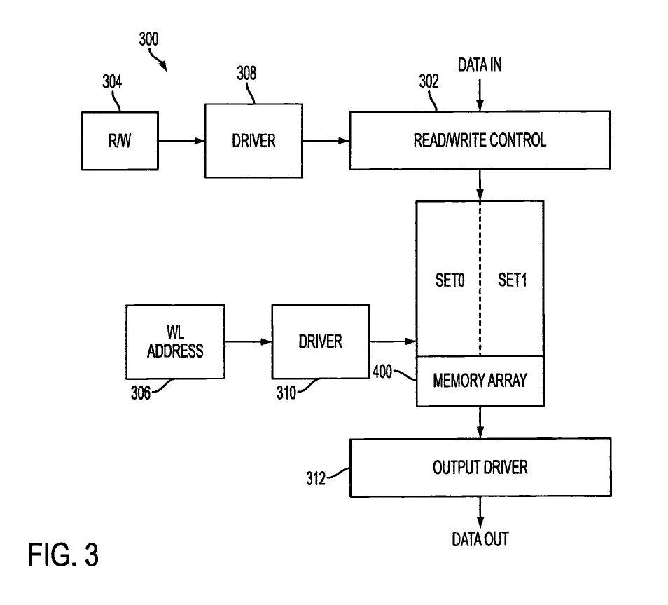

FIG. 3 illustrates a block diagram of an exemplary embodiment of a memory system 300. The memory system 300 includes a memory array 400 that receives data from a read/write controller 302 (processor) that receives read/write instructions 304 via a driver 308 (processor). A word line (WL) address 306 is sent to the memory array 400 via a driver 310. An output driver 312 receives data from the memory array 400 and outputs the data.

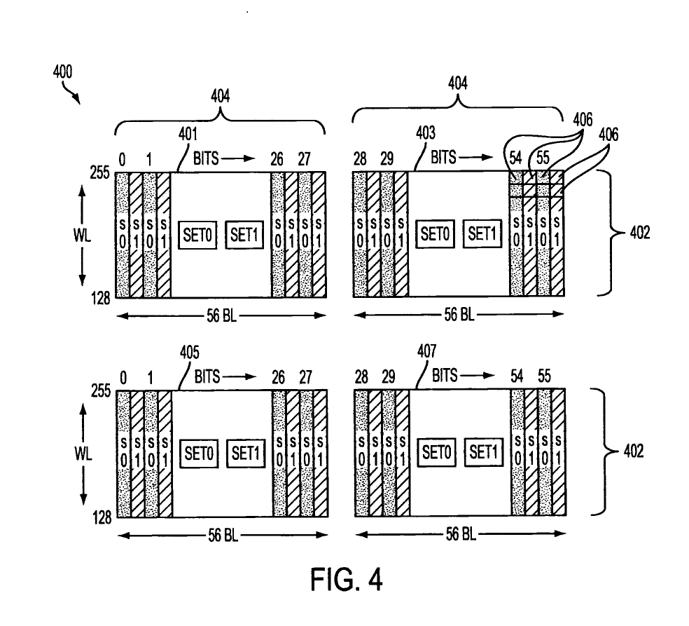

FIG. 4 illustrates an exemplary embodiment of the memory array 400 of FIG. 4. The memory array 400 includes four sub-arrays 401, 403, 405, and 407. The sub-arrays 401, 403, 405, and 407 each include 128 word lines (WL) 402 arranged in rows and 56 bit lines (BL) 404 arranged in columns that define 7168 cells 406 in each sub array. In the illustrated embodiment, the sub-arrays 405 and 407 include word lines 402 addressed 0-127 while the sub-arrays 401 and 403 include the word lines 402 addressed 128-255. The bit lines alternate between sets (set0 and set1) such that a set0 cell is adjacent to a set1 cell; that is adjacent to a set0 cell; and so on.

In operation, an eight bit data address is decoded that includes an eight bit word line address. No bit line address or bit decode is being used, as contrasted to the prior art described above. The word line address identifies a specific word line (0-255). For example, an eight bit address that identifies the word line 128 may be decoded. When decoded, the word line 128 is activated in the sub-arrays 401 and 403. The activation of the word line 128 row will include the activation of the 112 cells in the word line 128, by, for example, applying a voltage or current to the cells. Data may then be written to the cells of the word line 128 or read from the cells of the word line 128. Since each word line 402 has a unique and unshared address, only one word line is activated when an address is received. By activating one word line, power consumption is reduced when the array 400 is accessed.

The alternation of the bit lines 404 between set0 and set1 allows for error correction code (ECC) type corrections since a double bit error (an error on adjacent cells) will occur on both sets. Thus, an ECC correction scheme may be used on each set independently to correct the bit error of the respective cells.

The illustrated embodiment of FIGS. 3 and 4 include four sub-arrays that each include 56 bit lines and 128 word lines. The illustrated embodiment is but one example. Similar embodiments having any alternate number of bit lines and word lines may be arranged and operated in a similar manner using, for example an addressing scheme with an alternate number of bits.

The technical effects and benefits of the above described embodiments include a reduction in the power consumption of a memory array while maintaining an arrangement conducive to error correction code schemes.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A memory array including a plurality of memory cells, wherein each cell of the plurality of memory cells is defined by a row and a column, wherein each row includes a unique identifying address, and wherein each column is associated with one of two sets, the columns arranged such that a column associated with a first set is adjacent to a column of a second set.

2. The array of claim 1, wherein the array includes a plurality of sub-arrays.

3. The array of claim 2, wherein a first sub-array includes cells associated with the first set and cells associated with the second set.

4. The array of claim 1, wherein the array is operative to activate a single row identified by the unique identifying address.

5. The array of claim 1, wherein the unique identifying address is an eight bit address.

6. The array of claim 1, wherein the array is operative to read or write data on a single activated row identified by the unique identifying address.

7. A memory array system including:
a read/write controller operative to receive data;
a memory array including a plurality of memory cells, wherein each cell of the plurality of memory cells is defined by a row and a column, wherein each row includes a unique identifying address, and wherein each column is associated with one of two sets, the columns arranged such that a column associated with a first set is adjacent to a column of a second set, the memory array operative to store the data in the plurality of memory cells; and
an output driver operative to receive and output the data.

8. The system of claim 7, wherein the array includes a plurality of sub-arrays.

9. The system of claim 8, wherein a first sub-array includes cells associated with the first set and cells associated with the second set.

10. The system of claim 7, wherein the array is operative to activate a single row identified by the unique identifying address.

11. The system of claim 7, wherein the unique identifying address is an eight bit address.

12. The system of claim 7, wherein the array is operative to read or write data on a single activated row identified by the unique identifying address.

13. The system of claim 7, wherein the read/write controller includes a processor.

14. A method for accessing a memory array, the method including:
receiving an address;
decoding the address to determine a word line address uniquely identifying a row in the memory array; and
activating memory cells associated with the identified row, wherein the memory cells associated with the identified row are each associated with one of two sets and arranged such that a memory cell associated with a first set is adjacent to a memory cell associated with a second set.

15. The method of claim 14, wherein the method further includes:
receiving data; and
writing the data to the activated memory cells.

16. The method of claim 14, wherein the method further includes:
retrieving data from the activated memory cells; and
outputting the data.

17. The method of claim 14, wherein activating memory cells includes applying a voltage across the memory cells.

18. The method of claim 14, wherein the address comprises the word line address.
